(19) United States
(12) Patent Application Publication
(10) Pub. No.: US 2007/0141395 A1
(43) Pub. Date: Jun. 21, 2007

(54) Organic electroluminescent display device and method of preparing the same

(76) Inventors: Min-Seung Chun, Suwon-si (KR); Mi-Kyung Kim, Suwon-si (KR); Dong-Hun Kim, Suwon-si (KR); Jung-Ha Son, Suwon-si (KR); Jae-Hyun Kwak, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/599,016

(22) Filed: Nov. 13, 2006

(30) Foreign Application Priority Data
Dec. 20, 2005 (KR) 10-2005-0126102

(51) Int. Cl. H01L 51/54; H01L 51/52

(52) U.S. Cl. 428/690; 428/917; 313/504; 313/506; 257/E51.05; 427/66

(57) ABSTRACT

An organic EL display device and a method of manufacturing the same are disclosed. One embodiment of the organic EL display device includes: a light-emitting layer between a first electrode and a second electrode; a hole injection layer and a hole transport layer between the first electrode and the light-emitting layer; and a charge generation layer between the hole injection layer and the hole transport layer. The charge generation layer between the hole injection layer and the hole transport layer results in a low driving voltage, high efficiency and a long lifespan of the organic EL display device.

### CROSS-REFERENCE TO RELATED APPLICATION

This application claims the benefit of Korean Patent Application No. 10-2005-0126102, filed on Dec. 20, 2005, in the Korean Intellectual Property Office, the disclosure of which is incorporated herein in its entirety by reference.

### BACKGROUND

1. Field

The present disclosure relates to an organic electroluminescent (EL) display device and a method of manufacturing the same, and more particularly, to an organic EL display device having a charge generation layer between a hole injection layer and a hole transport layer and a method of manufacturing the same.

2. Description of the Related Technology

Electroluminescent (EL) devices, which are self light emitting display devices, have a wide viewing angle, excellent contrast and quick response time. EL devices are classified into inorganic EL devices and organic EL devices depending on the materials used to form emitting layers. Organic EL devices are brighter than inorganic EL devices. In addition, organic EL devices have lower driving voltages and quicker response time than inorganic EL devices. Furthermore, organic EL devices can generate multiple colors.

Typically, an organic EL display device includes an anode formed over a substrate. A hole transport layer (HTL), an light-emitting layer (EML), an electron transport layer (ETL) and a cathode are stacked sequentially over the HTL. The HTL, EML and ETL are organic thin films formed of organic compounds.

When a voltage is applied between the anode and cathode of an organic EL device, holes injected from the anode are transported to the EML through the HTL. On the other hand, electrons injected from the cathode are transported to the EML though the ETL. Then, excitons are generated by a recombination of the holes and electrons in the EML. The excitons, while returning to their ground state, make fluorescent molecules of the EML emit light to form an image.

For top emission organic EL display devices, as the device profile becomes thicker, the microcavity effect increases and emission defects due to impurities decrease. The microcavity effect refers to a variation in a wavelength of light emitting from an EL display device according to a path along which the light travels.

However, a thick profile device may have a high driving voltage. To maximize efficiency, an optimal path needs to be set to emit light having a wavelength close to the original wavelength of the light. The path can be set by regulating the thicknesses of organic layers of the device. Typically, light having a longer wavelength tends to be obtained when a thicker organic layer is used. That is, red light is obtained by using thicker organic layers while blue light is obtained by using thinner organic layers. Therefore, an optimal range of thickness for an organic layer may be determined based on the desired wavelength of light. The range of the thickness has a preferable period thickness and thus a maximum light extraction efficiency can be obtained. A one-period thickness may be too thin to prevent emission defects due to particles. A two-period thickness may be too thick to prevent an increase in the driving voltage even though the two-period thickness may prevent emission defects due to particles.

### SUMMARY

One embodiment provides an organic electroluminescent (EL) display device comprising: a first electrode; a second electrode; a light-emitting layer interposed between the first electrode and the second electrode; a hole injection layer interposed between the first electrode and the light-emitting layer; a hole transport layer interposed between the hole injection layer and the light-emitting layer; and a charge generation layer interposed between the hole injection layer and the hole transport layer.

The charge generation layer may be formed of a compound represented by Formula 1 below:

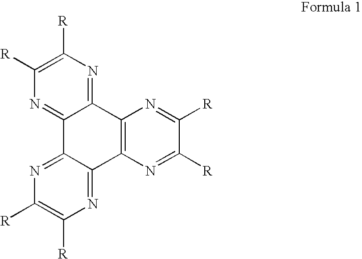

wherein R is selected from the group consisting of a nitrile group (—CN), a sulfone group (—SO₂R′), a sulfoxide group (—SOR′), a sulfoneamide group (—SO₂NR′₂), a sulfonate group (—SO₃R′), a nitro group (—NO₂), and a trifluoromethyl group (—CF₃); and wherein R′ is selected from the group consisting of an alkyl group, an aryl group, and a heterocyclic group of C₁-C₆₀ which is unsubstituted or substituted with an amine, an amide, an ether, or an ester.

The charge generation layer may be formed of a compound selected from the group consisting of hexanitril hexa-azatriphenylene, tetrafluoro-tetracyano-quinodimethane (F₄-TCNQ), FeCl₃, F₁₆CuPc and a metal oxide. The metal oxide may be selected from the group consisting of vanadium oxide (V₂O₅), rhenium oxide (Re₂O₇) and indium tin oxide (ITO).

The charge generation layer may comprise a first material having a lowest unoccupied molecular orbital energy level. The hole injection layer comprises a second material having a highest occupied molecular orbital energy level. A difference between the lowest unoccupied molecular orbital energy level of the first material and the highest occupied molecular orbital energy level of the second material may be in a range of about −2 eV to about +2 eV.

The device may comprise a plurality of pixels, and the charge generation layer may form a common layer for at least two of the pixels. The charge generation layer may have a thickness of about 10 Å to about 200 Å. The charge generation layer may have a thickness of about 20 Å to about 80 Å.

The organic EL display device may further comprise at least one layer selected from the group consisting of a hole blocking layer, an electron transport layer and an electron injection layer interposed between the light-emitting layer and the second electrode. The organic EL display device may further comprise an electron transport layer interposed between the second electrode and the light-emitting layer. The organic EL display device may further comprise a substrate, wherein the first electrode is formed over the substrate. The organic EL display device may further comprise an electron injection layer interposed between the electron transport layer and the second electrode. The organic EL display device may further comprise a hole blocking layer interposed between the electron transport layer and the light emitting layer.

Another aspect of the invention provides an electronic device comprising the organic EL display device described above.

Yet another aspect of the invention provides a method of manufacturing an organic EL display device. The method comprises: forming a hole injection layer over a first electrode; forming a charge generation layer over the hole injection layer; and forming a hole transport layer over the charge generation layer.

The method may further comprise: forming a light-emitting layer over the hole transport layer; and forming a second electrode over the light-emitting layer. The method may further comprise forming at least one of a hole blocking layer, an electron transport layer and an electron injection layer after forming the light-emitting layer and before forming the second electrode.

The charge generation layer may be formed of a compound represented by formula 1 below:

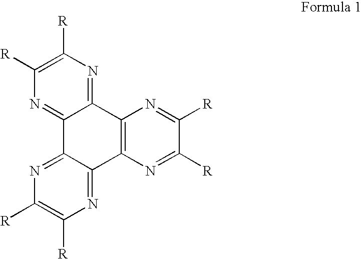

wherein R is selected from the group consisting of a nitrile group (—CN), a sulfone group (—SO₂R′), a sulfoxide group (—SOR′), a sulfoneamide group (—SO₂NR′₂), a sulfonate group (—SO₃R′), a nitro group (—NO₂), and a trifluoromethyl group (—CF₃), and wherein R′ is selected from the group consisting of an alkyl group, an aryl group, and a heterocyclic group of C₁-C₆₀ which is unsubstituted or substituted with an amine, an amide, an ether, or an ester.

The charge generation layer may be formed of a compound selected from the group consisting of hexanitril hexa-azatriphenylene, tetrafluoro-tetracyano-quinodimethane (F₄-TCNQ), FeCl₃, F₁₆CuPc and a metal oxide. The metal oxide may be selected from the group consisting of vanadium oxide (V₂O₅), rhenium oxide (Re₂O₇) and indium tin oxide (ITO).

The charge generation layer may comprise a first material having a lowest unoccupied molecular orbital energy level. The hole injection layer may comprise a second material having a highest occupied molecular orbital energy level. A difference between the lowest unoccupied molecular orbital energy level of the first material and the highest occupied molecular orbital energy level of the second material may be in a range of about −2 eV to about +2 eV. Forming the charge generation layer may comprise using resistance heating vapor deposition, electron beam vapor deposition, laser beam vapor deposition or sputtering deposition. The charge generation layer may have a thickness of about 10 Å to about 200 Å.

Another embodiment provides an organic EL display device having a low driving voltage and method of manufacturing the organic EL display device.

Another embodiment provides an organic electroluminescent (EL) display device including: a first electrode; a second electrode; a light-emitting layer between the first electrode and the second electrode; a hole injection layer between the first electrode and the light-emitting layer; a hole transport layer between the first electrode and the light-emitting layer; and a charge generation layer between the hole injection layer and the hole transport layer.

Yet another embodiment provides a method of manufacturing an organic EL display device which has a light-emitting layer between first and second electrodes, the method including: forming a hole injection layer on the first electrode; forming a charge generation layer on the hole injection layer: and forming a hole transport layer on the charge generation layer.

### BRIEF DESCRIPTION OF THE DRAWINGS

The above and other features and advantages of the instant disclosure will become more apparent by describing in detail exemplary embodiments thereof with reference to the attached drawings in which:

FIG. 1 is; a cross-sectional view of an organic electroluminescent (EL) display device; and

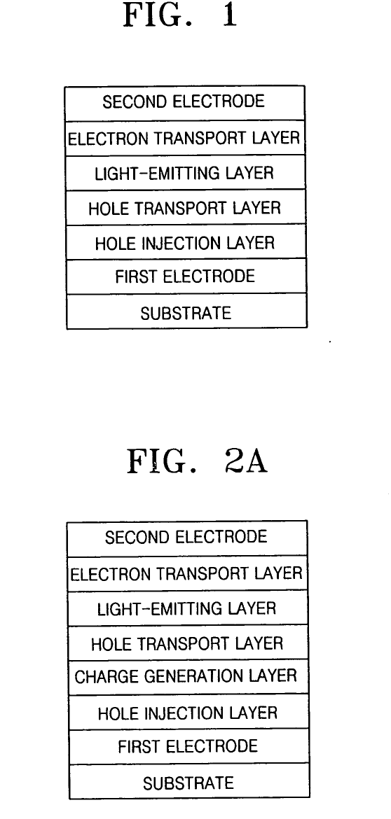

FIGS. 2A through 2C are cross-sectional views of organic EL display devices according to embodiments.

### DETAILED DESCRIPTION OF CERTAIN INVENTIVE EMBODIMENTS

Hereinafter, the instant disclosure will be described more fully with reference to the accompanying drawings, in which exemplary embodiments are shown.

An organic electroluminescent (EL) display device according to an embodiment includes a first electrode and a second electrode. The device also includes a light-emitting layer (EML) between the first and second electrodes. The device further includes a hole injection layer (HIL) and a hole transport layer (HTL) between the first electrode and the EML. In addition, the device may include a charge generation layer between the HIL and the HTL.

A material for the charge generation layer may include a compound represented by Formula 1 below:

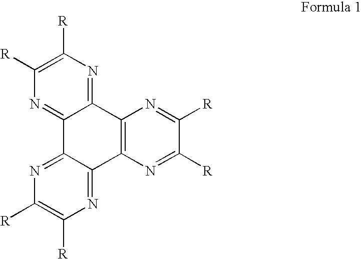

In Formula 1, R is a nitrile group (—CN), a sulfone group (—SO₂R′), a sulfoxide group (—SOR′), a sulfoneamide group (—SO₂NR′₂), a sulfonate group (—SO₃R′), a nitro group (—NO₂), or a trifluoromethyl group (—CF₃). Also, R′ is an alkyl group, an aryl group, or a heterocyclic group of C₁-C₆₀ which is unsubstituted or substituted with an amine, an amide, an ether, or an ester.

Examples of compounds of Formula 1 include, but are not limited to the following compounds:

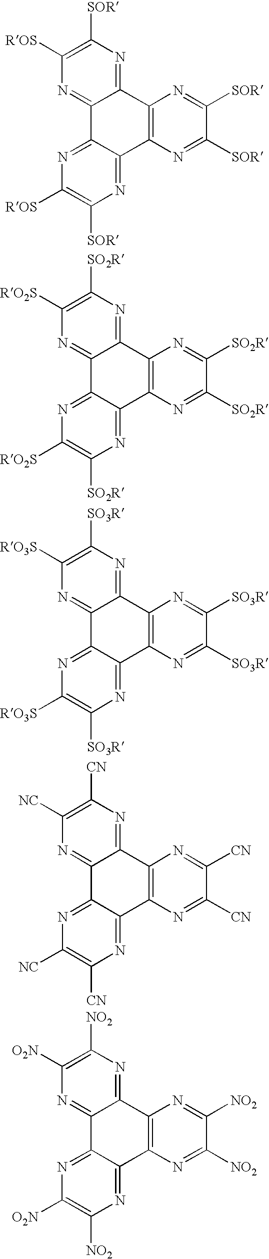

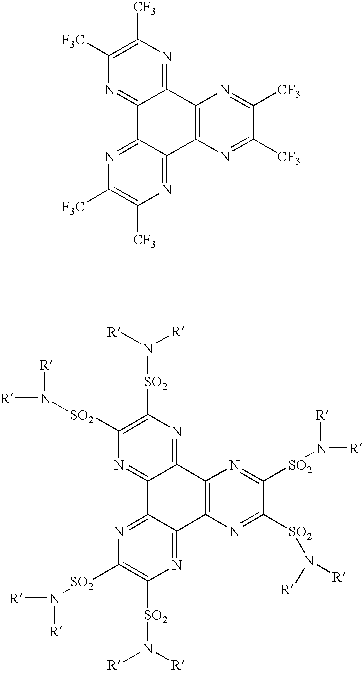

In the above examples, R′ is an alkyl group, an aryl group, or a heterocyclic group of C₁-C₆₀ which is unsubstituted or substituted with an amine, an amide, an ether, or an ester. The organic materials represented by the formulae above are for illustrative purposes only, and the invention is not limited to the formulae.

In addition, the charge generation layer may be formed of a compound selected from hexanitrile hexa-azatriphenylene, tetrafluoro-tetracyano-quinodimethane (F₄-TCNQ), FeCl₃, F₁₆CuPc and a metal oxide. The metal oxide may be vanadium oxide (V₂O₅), rhenium oxide (Re₂O₇) or indium tin oxide (ITO).

A difference between the lowest unoccupied molecular orbital (LUMO) energy level of a material for the charge generation layer and the highest occupied molecular orbital (HOMO) energy level of a material for the HIL may be in a range of about −2 eV to about +2 eV. For example, hexa-azatriphenylene has a HOMO energy level of about 9.6 to 9.7 eV and a LUMO energy level of about 5.5 eV. The HOMO energy level of tetrafluoro-tetracyano-quinodimethane (F₄-TCNQ) is about 8.53 eV, and the LUMO energy level of tetrafluoro-tetracyano-quinodimethane (F₄-TCNQ) is about 6.23 eV. The average HOMO energy level of a material for the HIL in an organic EL device is in a range of about 4.5 to about 5.5 eV. Accordingly, when hexa-azatriphenylene is used for the charge generation layer, a difference between the LUMO energy level of the charge generation layer and the HOMO energy level of the HIL may range from about 0 eV to about 1.0 eV. In another embodiment, when tetrafluoro-tetracyano-quinodimethane (F₄-TCNQ) is used for the charge generation layer, a difference between the LUMO energy level of the charge generation layer and the HOMO energy level of the HIL may range from about 0.73 to about 1.73 eV. The driving voltage can be reduced by the charge generation layer formed between the HIL and the HTL.

The charge generation layer can be formed using any suitable method. Examples of such methods include, but are not limited to: resistance heating vapor deposition, electron beam vapor deposition, laser beam vapor deposition and sputtering deposition. When the charge generation layer is formed of the compound represented by Formula 1 in which R′ is a C₅-C₆₀ alkyl group which is unsubstituted or substituted with an amine, an amide, an ether, or an ester, the charge generation layer can be formed by a process using a solution, such as inkjet printing, spin-coating, doctor-blading, roll coating, etc., instead of deposition. The charge generation layer can be formed as a common layer for all pixels. The thickness of the charge generation layer can be about 10 Å to about 200 Å, optionally about 20 Å to about 80 Å. When the thickness of the charge generation layer is less than 10 Å, charge generation is low, and when the thickness of the charge generation layer is greater than 200 Å, the driving voltage is high and the possibility of cross-talk due to a leakage current arises.

The organic EL display device may further include at least one of a hole blocking layer (HBL), an electron transport layer (ETL) and an electron injection layer (EIL) between the EML and the second electrode.

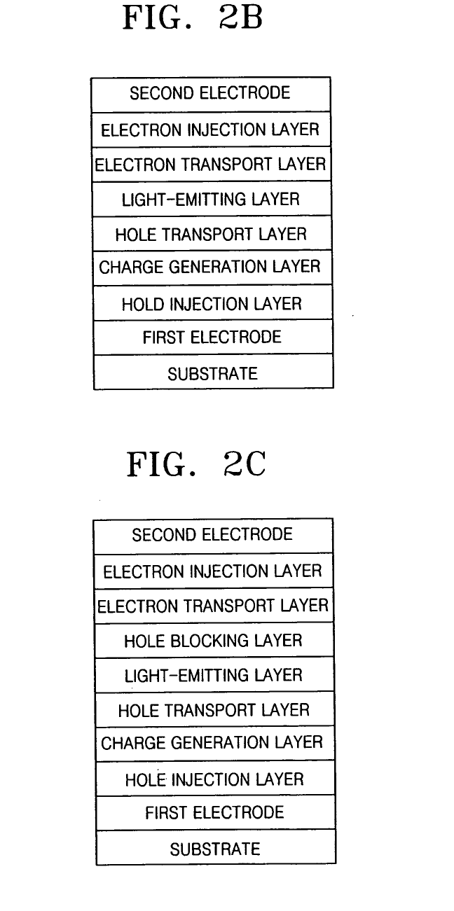

A method of manufacturing an organic EL display device which includes an EML between a first and a second electrode according to an embodiment includes forming a HIL on the first electrode, forming a charge generation layer on the HIL, and forming a HTL on the charge generation layer. The method of manufacturing the organic EL display device according to an embodiment will be described in detail with reference to FIGS. 2A through 2C. First, an anode (a first electrode) may be formed on a substrate. The substrate can be any substrate suitable for an organic EL display device. The substrate may be formed of glass or a plastic material. The plastic material may have excellent transparency and surface smoothness. The plastic material may be easily processed and may be water-proof. The anode can be formed of a high work function metal (≧ about 4.5 eV), such as indium tin oxide (ITO), indium zinc oxide (IZO), tin oxide (SnO₂), zinc oxide (ZnO), or any suitable transparent material which has high conductivity.

Then, an HIL can be formed on the anode using high vacuum thermal evaporation deposition. Depending on the type of material used to form the HIL, the HIL can also be formed using a solution containing the material by spin-coating, dip-coating, doctor-blading, inkjet printing, thermal transfer, organic vapor phase deposition (OVPD), etc.

The HIL may be formed by one of the methods described above such as vacuum thermal deposition, spin-coating, etc. The thickness of the HIL can be about 100 Å to about 2500 Å. When the thickness of the HIL is less than 100 Å, the hole injecting ability is low, and when the thickness of the HIL is greater than 2500 Å, the driving voltage is high. In one embodiment for a top emission structure device, the thickness of the HIL may be about 1000 Å to about 2500 Å. A skilled artisan will appreciate that the thickness may vary depending on the color of light which the device emits.

Examples of the material used to form the HIL include, but are not limited to, copper phthalocyanin (CuPc) or a starbust type amine such as TCTA, m-MTDATA or IDE406 (available from Idemitsu Kosan Co., Ltd., Tokyo, Japan). Below are formulas of CuPc, TCTA, and m-MTDATA.

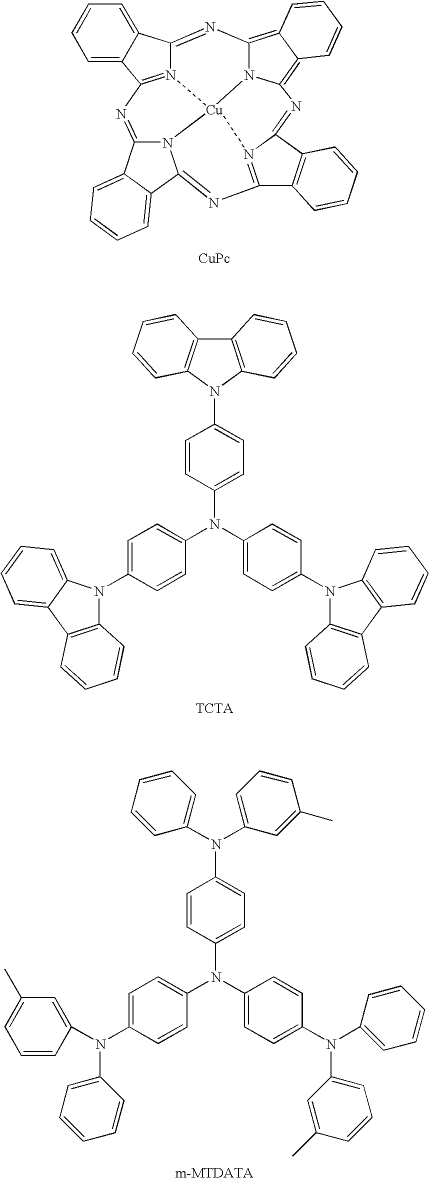

A charge generation layer may be formed on the HIL. Examples of the material for the charge generation layer include, but are not limited to, a compound represented by Formula 1 below:

### Formula 1

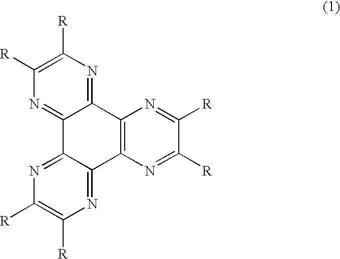

In Formula 1, K is a nitrile group (—CN), a sulfone group (—SO₂R′), a sulfoxide group (—SOR′), a sulfoneamide group (—SO₂NR′₂), a sulfonate group (—SO₃R′), a nitro group (—NO₂), or a trifluoromethyl group (—CF₃). Also, R′ is an alkyl group, an aryl group, or a heterocyclic group of C₁-C₆₀ which is unsubstituted or substituted with an amine, an amide, an ether, or an ester.

The charge generating material may be hexanitril hexa-azatriphenylene, tetrafluoro-tetracyano-quinodimethane (F₄-TCNQ), FeCl₃, F₁₆CuPc or a metal oxide. The metal oxide can be vanadium oxide (V₂O₅), rhenium oxide (Re₂O₇) or indium tin oxide (ITO).

The charge generation layer can be formed on the HIL using resistance heating vapor deposition, electron beam vapor deposition, laser beam vapor deposition or sputtering. The charge generation layer can be formed as a common layer for all pixels. The thickness of the charge generation layer can be about 10 Å to about 200 Å, optionally about 20 to about 80 Å. When the thickness of the charge generation layer is less than 10 Å, charge generation is low, and when the thickness of the charge generation layer is greater than 200 Å, the driving voltage is high and the possibility of cross-talk due to a leakage current arises.

The HTL may be formed on the charge generation layer using various processes such as vacuum thermal deposition or spin-coating. The material that is used to form the HTL is not limited. Examples of the material include N,N′-bis(3-methylphenyl)-N,N′-diphenyl-[1,1-biphenyl]-4,4′-diamine (TPD), N,N′-di(naphthalene-1-il)-N,N′-diphenyl benzidine (α-NPD), and IDE 320 (available from Idemitsu Kosan Co., Ltd.). The thickness of the HTL can be about 50 Å to about 1500 Å. The chemical formulas of TPD and α-NPD are as followsWhen the thickness of the HTL is less than 50 Å, the hole transporting ability is low, and when the thickness of the HTL is higher than 1500 Å, the driving voltage is high.

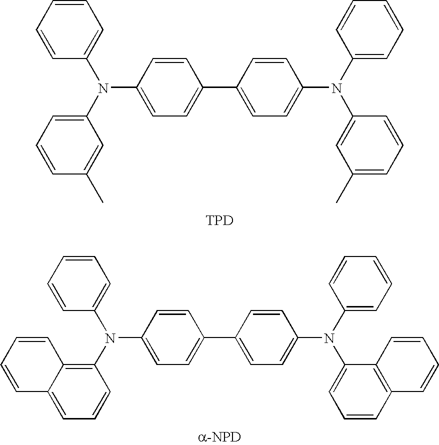

An EML may be formed on the HTL. The process of forming the EML is not limited. Various processes such as vacuum deposition, inkjet printing, laser printing, photolithography and OVPD can be used. The thickness of the EML can be about 100 Å to about 800 Å.

When the thickness of the EML is less than 100 Å, the efficiency and lifespan of the organic EL display device are low, and when the thickness of EML is greater than 800 Å, the driving voltage is high. A hole blocking layer (HBL) may be selectively formed on the EML by one of the methods described above such as vacuum deposition, spin-coating, etc. The material that is used to form the HBL is not limited. The material is capable of transporting electrons and have a higher ionization potential than the light-emitting compound. Examples of the material for the HBL include Balq, BCP and TPBI. The thickness of the HBL can be about 30 Å to about 500 Å. The chemical formulas of Balq, BCP and TPBI are as follows. When the thickness of HBL is less than 30 Å, efficiency decreases due to a poor hole blocking ability, and when the thickness of the HBL is greater than 500 Å, the driving voltage is high.

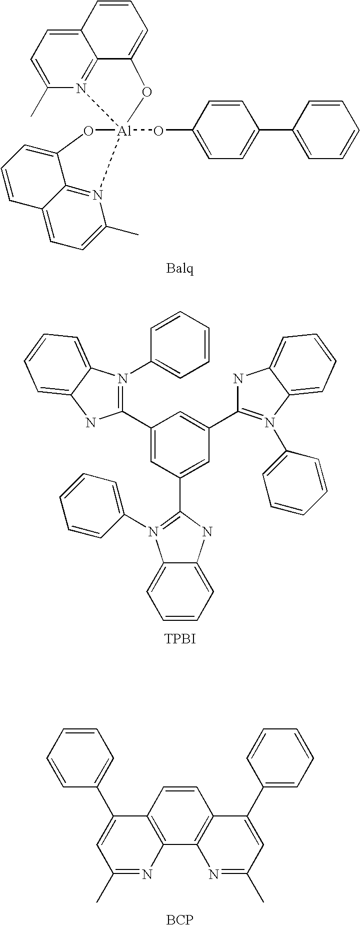

An electron transport layer (ETL) may be formed on the HBL using vacuum deposition or spin-coating. The material that is used to form the ETL is not limited, and may be Alq3. The thickness of the ETL can be about 50 Å to about 600 Å. When the thickness is less than 50 Å, the lifespan of the organic EL display device is low, and when the thickness is greater than 600 Å, the driving voltage is high.

An EIL may be selectively formed on the ETL. The material that is used to form the EIL can be LiF, NaCl, CsF, Li₂O, BaO or Liq. The thickness of the EIL can be about 1 Å to about 100 Å. Below is the chemical formula of Liq. When the thickness of EIL is less than 1 Å, the EIL can not perform its function properly, and when the thickness of the EIL is greater than 100 Å, the driving voltage is high since the EIL functions as a insulation layer.

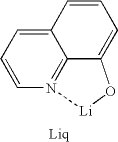

A cathode (a second electrode) may be formed on the EIL using one of vacuum thermal deposition, sputtering, metal-organic chemical vapor deposition, etc., thereby completing the organic EL display device. The metal used for the cathode can be Li, Mg, Al, Al—Li, Ca, Mg—In or Mg—Ag.

The organic EL display device of an embodiment may further include one or two intermediate layers between two of the anode, the HIL, the charge generation layer, the HTL, the EML, the ETL, the EIL and the cathode. In addition, an HBL and an electron blocking layer (EBL) can further be included in the organic EL display device.

Hereinafter, the instant disclosure will be described in more detail with reference to the following examples. The following examples are for illustrative purposes, and thus are not intended to limit the scope of the invention.

### EXAMPLE 1

A 15 Ω/cm² (1200 Å) ITO glass substrate manufactured by Corning Inc. (Corning, N.Y.) was cut into pieces of 50 mm×50 mm×0.7 mm in size, and each piece was ultrasonically cleaned in isopropyl alcohol and deionized water for 5 minutes and then UV/ozone cleaned for 30 minutes to form an anode.

M-MTDATA was vacuum deposited on the substrate to form an HIL with a thickness of 500 Å. Hexa-azatriphenylene was resistance-heating deposited on the HIL to form a charge generation layer with a thickness of 20 Å. N,N′-di(1-naphthyl)-N,N′-diphenyl benzidine(α-NPD) was vacuum deposited on the charge generation layer to form the hole transport layer with a thickness of 200 Å.

Vacuum deposition using organic vapor phase deposition (OVPD) was performed to form an EML with a thickness of about 300 Å. Alq3 as an electron transporting material was deposited on the EML to form an ETL with a thickness of about 300 Å. LiF was vacuum deposited on the electron transport layer to form an EIL with a thickness of 10 Å on the ETL and an Mg—Ag alloy was vacuum deposited on the EIL to form a cathode with a thickness of 200 Å, thereby completing an organic EL display device.

### EXAMPLE 2

An organic EL display device was manufactured in the same manner as in Example 1, except that the thickness of the charge generation layer was 50 Å.

### EXAMPLE 3

An organic EL display device was manufactured in the same manner as in Example 1, except that the thickness of the charge generation layer was 80 Å.

### COMPARATIVE EXAMPLE 1

A 15 Ω/cm² (1200 Å) ITO glass substrate manufactured by Corning Inc. was cut into pieces of 50 mm×50 mm×0.7 mm in size, and each piece was ultrasonically cleaned in isopropyl alcohol and deionized water for 5 minutes and then UV/ozone cleaned for 30 minutes to form an anode.

M-MTDATA was vacuum deposited on the substrate to form an HIL with a thickness of 1300 Å. N,N′-di(1-naphthyl)-N,N′-diphenyl benzidine(α-NPD) was vacuum deposited on the HIL to form an HTL with a thickness of 200 Å.

Vacuum deposition using OVPD was performed to form an EML with a thickness of about 300 Å. Alq3 as an electron transporting substance was deposited on the EML to form an ETL with a thickness of about 300 Å. LiF was vacuum deposited on the ETL to form an EIL with a thickness of 10 Å, and an Mg—Ag alloy was vacuum deposited on the EIL to form a cathode with a thickness of 200 Å, thereby completing an organic EL display device.

The driving voltages, efficiencies and lifespans of the organic EL display devices manufactured according to Examples 1 through 3 and Comparative Example 1 were measured. The results are shown in Table 1.

TABLE 1

| | Driving voltage (V) | Efficiency (cd/V) | Lifespan (hour) |
|---|---|---|---|
| Example 1 | 5.50 | 3.16 | 1,500 |
| Example 2 | 5.31 | 3.57 | 1,500 |
| Example 3 | 5.22 | 4.16 | 1,500 |
| Comparative | 6.08 | 3.04 | 1,000 |
| Example 1 | | | |

The driving voltages of the organic EL devices obtained in Examples 1 through 3 were in the range of 5.50 to 5.22 V, and the driving voltage of the EL device obtained in Comparative Example 1 was 6.08 V.

The efficiencies of the organic EL devices obtained in Examples 1 through 3 were in the range of 3.16 to 4.16 cd/A at a brightness of 400 cd/m². The efficiency of the organic EL device obtained in Comparative Example 1 was 3.04 cd/A at a brightness of 400 cd/m².

The lifespan indicates time taken for a brightness to decrease to 50% of the initial brightness. The lifespans of the organic EL display devices obtained in Examples 1 through 3 were about 1,500 hours at 5,000 cd/m², and the lifespan of the organic EL display device obtained in Comparative Example 1 was 1,000 hours at 5,000 cd/m². Accordingly, the lifespan of the organic EL display device of Example 1 was than 1.5 times longer than the lifespan of the organic EL display device of Comparative Example 1.

The organic EL display device of the embodiments has the charge generation layer between the HIL and the HTL, and thus, the driving voltage of the EL display device is low, and the efficiency of the EL display device is high, and the lifespan of the organic EL display device is long.

While the instant disclosure has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic electroluminescent (EL) display device comprising:
a first electrode;
a second electrode;
a light-emitting layer interposed between the first electrode and the second electrode;
a hole injection layer interposed between the first electrode and the light-emitting layer;
a hole transport layer interposed between the hole injection layer and the light-emitting layer; and
a charge generation layer interposed between the hole injection layer and the hole transport layer.

2. The organic EL display device of claim 1, wherein the charge generation layer is formed of a compound represented by Formula 1 below: 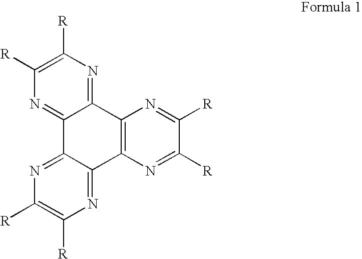
wherein R is selected from the group consisting of a nitrile group (—CN), a sulfone group (—SO₂R′), a sulfoxide group (—SOR′), a sulfoneamide group (—SO₂NR′₂), a sulfonate group (—SO₃R′), a nitro group (—NO₂), and a trifluoromethyl group (—CF₃); and
wherein R′ is selected from the group consisting of an alkyl group, an aryl group, and a heterocyclic group of C₁-C₆₀ which is unsubstituted or substituted with an amine, an amide, an ether, or an ester.

3. The organic EL display device of claim 1, wherein the charge generation layer is formed of a compound selected from the group consisting of hexanitril hexa-azatriphenylene, tetrafluoro-tetracyano-quinodimethane (F₄-TCNQ), FeCl₃, F₁₆CuPc and a metal oxide.

4. The organic EL display device of claim 3, wherein the metal oxide is selected from the group consisting of vanadium oxide (V₂O₅), rhenium oxide (Re₂O₇) and indium tin oxide (ITO).

5. The organic EL display device of claim 1, wherein the charge generation layer comprises a first material having a lowest unoccupied molecular orbital energy level, wherein the hole injection layer comprises a second material having a highest occupied molecular orbital energy level, and wherein a difference between the lowest unoccupied molecular orbital energy level of the first material and the highest occupied molecular orbital energy level of the second material is in a range of about −2 eV to about +2 eV.

6. The organic EL display device of claim 1, wherein the device comprises a plurality of pixels, and wherein the charge generation layer forms a common layer for at least two of the pixels.

7. The organic EL display device of claim 1, wherein the charge generation layer has a thickness of about 10 Å to about 200 Å.

8. The organic EL display device of claim 7, wherein the charge generation layer has a thickness of about 20 Å to about 80 Å.

9. The organic EL display device of claim 1, further comprising at least one layer selected from the group consisting of a hole blocking layer, an electron transport layer and an electron injection layer interposed between the light-emitting layer and the second electrode.

10. The organic EL display device of claim 1, further comprising an electron transport layer interposed between the second electrode and the light-emitting layer.

11. The organic EL display device of claim 10, further comprising a substrate, wherein the first electrode is formed over the substrate.

12. The organic EL display device of claim 11, further comprising an electron injection layer interposed between the electron transport layer and the second electrode.

13. The organic EL display device of claim 12, further comprising a hole blocking layer interposed between the electron transport layer and the light emitting layer.

14. An electronic device comprising the organic EL display device of claim 1.

15. A method of manufacturing an organic EL display device, the method comprising:
forming a hole injection layer over a first electrode;
forming a charge generation layer over the hole injection layer; and
forming a hole transport layer over the charge generation layer.

16. The method of claim 15, further comprising:
forming a light-emitting layer over the hole transport layer; and
forming a second electrode over the light-emitting layer.

17. The method of claim 16, further comprising forming at least one of a hole blocking layer, an electron transport layer and an electron injection layer after forming the light-emitting layer and before forming the second electrode.

18. The method of claim 15, wherein the charge generation layer is formed of a compound represented by formula 1 below: 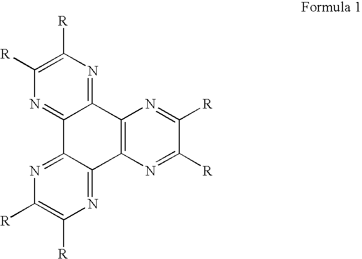
wherein R is selected from the group consisting of a nitrile group (—CN), a sulfone group (—SO₂R′), a sulfoxide group (—SOR′), a sulfoneamide group (—SO₂NR′₂), a sulfonate group (—SO₃R′), a nitro group (—NO₂), and a trifluoromethyl group (—CF₃), and
wherein R′ is selected from the group consisting of an alkyl group, an aryl group, and a heterocyclic group of C₁-C₆₀ which is unsubstituted or substituted with an amine, an amide, an ether, or an ester.

19. The method of claim 15, wherein the charge generation layer is formed of a compound selected from the group consisting of hexanitril hexa-azatriphenylene, tetrafluoro-tetracyano-quinodimethane (F₄-TCNQ), FeCl₃, F₁₆CuPc and a metal oxide.

20. The method of claim 15, wherein the metal oxide is selected from the group consisting of vanadium oxide (V₂O₅), rhenium oxide (Re₂O₇) and indium tin oxide (ITO).

21. The method of claim 15, wherein the charge generation layer comprises a first material having a lowest unoccupied molecular orbital energy level, wherein the hole injection layer comprises a second material having a highest occupied molecular orbital energy level, and wherein a difference between the lowest unoccupied molecular orbital energy level of the first material and the highest occupied molecular orbital energy level of the second material is in a range of about −2 eV to about +2 eV.

22. The method of claim 15, wherein forming the charge generation layer comprising using resistance heating vapor deposition, electron beam vapor deposition, laser beam vapor deposition or sputtering deposition.

23. The method of claim 15, wherein the charge generation layer has a thickness of about 10 Å to about 200 Å.
